(19) United States
(12) Patent Application Publication
(10) Pub. No.: US 2013/0076360 A1
(43) Pub. Date: Mar. 28, 2013

(54) POWER MODULE AND MANUFACTURING PROCESS

(71) Applicant: Adam Albrecht, Nuernberg (DE)

(72) Inventor: Adam Albrecht, Nuernberg (DE)

(21) Appl. No.: 13/631,455

(22) Filed: Sep. 28, 2012

(30) Foreign Application Priority Data
Sep. 28, 2011 (DE) DE 102011083598.9

(51) Int. Cl. G01R 33/34; H05K 13/04; H03G 99/00

(52) U.S. Cl. 324/322; 330/185; 29/825

(57) ABSTRACT

A power module for a high frequency amplifier unit is provided. The power module includes a base support plate, on which at least one power electronic module is contacted via a number of contact pins. A shield plate is arranged on a side of the power electronic module facing away from the base support plate. The power electronic module is in contact with a cooling element at a side facing the shield plate.

This application claims the benefit of DE 10 2011 083 598.9, filed on Sep. 28, 2011.

### BACKGROUND

The present embodiments relate to a power module for a high frequency amplifier unit.

A power module may be suitable for transmitter arrangements in magnetic resonance tomographs, in which shielding from electromagnetic radiation or waves from power modules is to be provided. As power electronic modules such as transistors generate such radiation and may thus interfere with the operation of the magnetic resonance tomograph, shielding against interference effects is to be provided as comprehensively as possible with the aid of a shield plate.

FIG. 1 shows such a power module 1′ in accordance with the prior art. A base support plate 9 is provided, on a lower side, with a continuous copper layer 29 that serves as a contact for power electronic modules 3 (e.g., transistors 3). Each of the transistors 3 is connected (e.g., brought into contact with) to the base support plate 9 through soldering via contact pins 5. The entire surface of each transistor is also soldered to the copper layer 29. On an opposite side of the transistors 3 to the base support plate 9 and above the transistors 3 is a shield plate 11a that also offers external electromagnetic shielding from the transistors 3 by two side walls 27. The side walls 27 also provide a mechanical connection between the base support plate 9 and the shield plate 11a.

A support 31 is arranged underneath the base support plate 9 on the opposite side of the transistors 3 to the shield plate 11a and, like the base support plate 9, also has a power supply transistor 23 for supplying power to the power electronic modules 3. The power input from the power supply transistor 23 in the direction of the power electronic modules 3 leads, via a connecting cable 25, to the upper side of the shield plate 11a and from there, via another connecting cable 33, to the base support plate 9. A cooling element 7 is arranged underneath each of the power electronic modules 3, facing the base support plate 9, and in each case, in a cavity in the copper layer 29 and the support 31. The cooling element 7 cools the power electronic modules 3.

The basic structure shown in FIG. 1 is costly to make. For example, the copper layer 29 is very heavy, as the copper layer 29 is continuous across the entire surface of the base support plate 9 and is of considerable thickness in order to be able sufficiently to divert heat in the direction of the cooling elements 7. The mass of the copper layer 29 therefore exceeds the mass of the base support plate 9 by many times. In addition, corresponding cavities are to be provided in the copper layer 29 and the support 31. This entails a costly manufacturing process. Another problem is that in such a structure, the lower sides of the power electronic modules 3 are to be continuously in contact with the base support plate 9 or the copper layer for cooling purposes. The contact pins 5 have tolerances with regard positioning and alignment. The tolerances may amount to a height difference of up to 20 μm in the area in contact with the base support plate 9. The planarity of the base support plate 9 may also vary by up to 10%. Thus, the conditions, under which the entire surface of the power electronic modules 3 is to be placed on the base support plate 9, are made considerably more difficult, as all the tolerances are to be compensated for, and mechanical stresses may develop. Again, this makes the manufacturing process more problematic (e.g., costly in terms of time and materials). This may also result in a larger quantity of scrap.

### SUMMARY AND DESCRIPTION

The present embodiments may obviate one or more of the drawbacks or limitations in the related art. For example, a power module may be more easily and efficiently provided or operated. The tolerances and/or the large mass in the area of the base support plate, and the manufacturing process made as simple and/or efficient and/or as sparing of materials as possible may obviate one or more of the drawbacks or limitations in the related art.

The power electronic module is in contact with a cooling element at a side facing the shield plate. The base support may have an integrated conductor structure and thus may be constructed as a board. In one embodiment and in contrast to the prior art, the surface of the board may not have a metal surface across an entire lower side but instead, conductor structures constructed as discreet structures with corresponding spaces between the conductor structures that have no conductor function.

For example, the power electronic module includes a transistor (e.g., a high power transistor with a power rating of at least 600 W). An ARF476F transistor sold by Microsemi may be used, for example. Bringing the power electronic module into contact with the cooling element may not bring the power electronic module physically into contact with the cooling element. Rather, a working relationship between the power electronic module and the cooling element is established, such that the cooling element is arranged so close to the power electronic module that the cooling element is able to take up a large percentage of the heat radiated by the power electronic module (e.g., at least 50%) and either absorb the or conduct the heat away during operation.

The previously held principle of lateral cooling of power electronic modules on the side, towards which the contact pins face, is thus departed from. Rather, all or part of the surface of the shield plate is already arranged on the upper side (e.g., on the other side of the power electronic module, facing away from the base support plate). Heat removal may be accomplished just as well on the upper side of the power electronic modules as heat removal may be accomplished on the lower side, but with the effect that contact between the surfaces of the power electronic modules and the base support plate becomes obsolete. Contact via the contact pins is sufficient. This results in it being much easier to compensate for component and surface tolerances in the area of contact between the base support plate and the power electronic module. The power electronics construction may thus be “suspended in mid-air” (e.g., only elastically supported by the contact pins). It is not necessary to adhere to narrow tolerances (e.g., of the contact pins or of the planarity of the base support plate). Power electronic modules and base support plates that do not adhere to the above-mentioned tolerance values may therefore be used, thus making it possible to use cheaper and more simply manufactured power electronic modules and base support plates.

The two purposes of establishing contact (e.g., of galvanic power transmission) and heat removal are functionally and spatially separated. With the shield plate already being on the opposite side of the electronic power module to the base support plate, a potentially load-bearing structure that may function as a load-bearing structure for the cooling element exists (e.g., just as the base support plate did before). In other words, the galvanic plane of contact is not the same as the plane of contact for cooling purposes.

Such a construction for a power module is suitable for application in magnetic resonance tomographs and, for example, for building into a high frequency amplifier unit that modulates electromagnetic fields in a body coil of the magnetic resonance tomograph. As the amplification values (e.g., of the transistors) are very high, and the construction space in a high frequency amplifier of this type is limited, both an arrangement of the power electronic modules that is as compact as possible and a high cooling density are to be provided. In addition, power modules in magnetic resonance tomographs must are to be electromagnetically shielded in order to avoid interference fields. A shield plate that defines a reference plane essentially parallel to a reference plane of the base support plate and serves as a support for the cooling element is thus already provided.

In one embodiment, a high frequency amplifier unit of a magnetic resonance tomography system (e.g., of a body coil of the magnetic resonance tomography system) is provided. The high frequency amplifier unit has a number of power modules and a high frequency antenna arrangement (e.g., a high frequency transmission arrangement of a body coil) with a high frequency antenna and a high frequency amplifier unit. A magnetic resonance tomography system with a high frequency antenna arrangement and a high frequency amplifier unit is also provided. In one embodiment, the power module is configured as a power module of a magnetic resonance tomography system (e.g., for a high frequency amplifier unit of a body coil of the magnetic resonance tomography system).

In one embodiment, a manufacturing method includes providing a base support plate and bringing at least one power electronic module into contact with a base support plate via a number of contact pins. A shield plate is arranged on a side of the power electronic module facing away from the base support plate. The method also includes bringing the power electronic module into contact with a cooling element at a side facing the shield plate.

Under this method, the sequence of acts used may be as enumerated here, although other sequences may be used.

Despite cooling being provided on an upper side, a cooling element may also be arranged underneath the power electronic module (e.g., in an area of the base support plate). For example, the cooling element may be a cooling element that extends around the power electronic module in the form of a ring or a “U” and thus extends both in the area, in which the power electronic module is in contact with the base support plate, and on the plane of the power electronic module that is opposite this plane. In such a case, the power electronic module is cooled along two sides of the power electronic module. This has the advantage that the power electronic module may be cooled quickly and effectively. In one embodiment, the base support plate may be configured without a cooling element and in an area above the base support plate, in which the power electronic module is positioned. This is because the height, to which the cooling element is constructed in the area of the base support plate, and the weight, may be as low as possible, as cooling is provided via the cooling element on the upper side of the power electronic module (e.g., on the side facing away from the base support plate). For example, the copper layer, with which the base support plate is provided, may not be continuous.

In one embodiment, the base support plate does not have a continuous contacting layer but instead, for example, has individual points and/or areas for galvanic contacting on a surface facing the power electronic module. In one embodiment, the result is lighter contact areas deliberately arranged on only parts of the surface where contacting with the power electronic module or other electronic components is to be provided.

A power module may have a single power electronic module arranged and cooled in this manner. In one embodiment, the power module may have multiple power electronic modules, the number of which depends on the construction and purpose (e.g., 8 or 12 transistors per power module). Four such power modules may, for example, be used in a high frequency amplifier unit of the abovementioned type. The savings effect achieved through reduced material costs and labor intensity is increased severalfold in such an application. For example, the power module may have at least two power electronic modules. At least these two power electronic modules may be in contact with the base support plate at surfaces of the base support plate that face away from each other. Power electronic modules are thus contacted at both the main surfaces of the base support plate. As a result, the quantity of power electronic modules on the same surface of the base support plate may potentially be doubled. Despite the quantity of power electronic modules being doubled in this way, the cooling provided will still be sufficient. This is due to the fact that at least one of the two power electronic modules is cooled on the side facing away from the base support plate. In one embodiment, both power electronic modules may be cooled by one cooling element (e.g., on the side facing away from the base support plate). Each of the cooling elements may be functionally allocated to one of the two power electronic modules. A cooling element that is shared by both power electronic modules may, however, also be used. Such a cooling element may extend in the form of a ring or a “U” and may be in contact with both power electronic modules through being brought into contact with each of the power electronic modules at sides of the power electronic modules that face away from the base support plate.

Alternatively or in addition, in a power module with at least two power electronic modules, two power electronic modules may be brought into contact with the base support plate on the same surface of the base support plate. The power electronic modules may thus be arranged in a row or in a matrix arrangement on the same surface of the base support plate and then be cooled, for example, by strand-like cooling elements running across those sides of the power electronic modules that face away from the base support plate, connecting the power electronic modules with one another along upper sides. This enables several power electronic modules to be cooled both simultaneously and effectively, as well as making it possible to achieve improved mechanical stabilization from above.

In the case of a power module with at least two power electronic modules, each of the power electronic modules may be in contact with, for example, a shared cooling element on the side facing away from the base support plate. The cooling element thus cools several power electronic modules simultaneously on the side facing away from the base support plate in each case. This saves both materials and construction space.

For the purposes of further signal processing or amplification, a grounding connection may be provided in addition to the usual outputs from power electronic modules.

In one embodiment, the power electronic module may have a grounding connection to the shield plate. The grounding connection is thus not or not exclusively, as has previously been the case, to the base support plate, but at least either exclusively to the shield plate or additionally to the shield plate.

In one embodiment, the power electronic module also has a grounding connection to the base support plate, and the shield plate may be mechanically connected to the base support plate via the grounding connection. This gives additional mechanical stabilization that may be achieved either through the grounding connection to the base support plate being via one or more contact pins, for example, or through the housing of the power electronic module, also grounded via the contact pins, being connected to the shield plate. The housing of the power electronic module may be connected to the shield plate via a screw or similar fixing joint (riveting), by soldering or conducting adhesive, or by any number of other options. The base support plate and shield plate are thus grounded or altered and at the same time, stably bonded to one another by a mechanical device.

Any devices that quickly conduct large amounts of heat out of (e.g., away from) the power electronic module are suitable as cooling elements. This may, for example, be achieved through simple metal plates of a sufficient thickness, but cooling provided by a cooling element that includes a hollow chamber may be used. Cooling provided by the cooling element that includes the hollow chamber is cheaper and saves materials and space. The hollow chamber may include a cooling fluid (e.g., a cooling fluid that flows through the hollow chamber). The cooling element is thus part of a system of channels, through which fluid flows and which may, for example, also include another built-in cooling unit located in a suitable position. As a result of the flow of cooling fluid, the cooling element may absorb sufficient heat outside the power module. Such a fluid may include gas. However, liquid may be used because of the greater heat absorption. A liquid, of which the heat conductivity at least equals the heat conductivity of water, may be used. Water is a good cooling fluid, for example.

Alternatively or in addition, the cooling element includes an insulation layer that is in direct contact with the power electronic module and electrically insulates and/or electromagnetically shields the power electronic module. Such an insulation layer may, for example, be composed of materials such as aluminum nitrite (AlN) or other insulating materials with similar heat conducting properties. The materials may have an electrically insulating and simultaneously electromagnetically shielding effect. Alternative materials to AlN are, for example, BeO (beryllium oxide) and Al₂O₃ (aluminum oxide). BeO conducts heat well but is poisonous, whereas Al₂O₃ does not conduct heat as well as either of the two other materials.

One advantage is that tolerances in the construction heights of the contact pins or in the planarity of the base support plate are no longer important because it is no longer necessary for the entire surface of the power electronic module to be in contact with the base support plate for the purpose of cooling. In one embodiment, part of the surface of the power electronic module may be in contact with the base support plate. Such a connection over part of the surface may only be composed of isolated connections (e.g., connections via the contact pins or a grounding connection). This produces an elastic mechanical connection between the power electronic module and the base support plate, for which construction tolerances are of no or little importance.

### BRIEF DESCRIPTION OF THE DRAWINGS

FIG. 1 shows a power module according to the prior art;

FIG. 2 shows a cross section of one embodiment of a power module;

FIG. 3 shows a plan view of the power module of FIG. 2 and a magnetic resonance tomograph; and

FIG. 4 shows a cross section of the power module along intersecting line IV-IV in FIG. 2.

### DETAILED DESCRIPTION OF THE DRAWINGS

FIG. 2 is a cross-sectional view of one embodiment of a power module 1 (e.g., a basic component of a high frequency amplifier) that has an output of, for example, 8 kW. Four of the power modules 1 may be arranged in the high frequency amplifier. Power electronic modules 3 (e.g., transistors 3) are arranged on either side of a base support plate 9. Two transistors 3 are arranged opposite each other on the base support plate 9. All the transistors 3 are connected both galvanically and mechanically to the base support plate 9 with the aid of first contact pins 5a (e.g., gate contacts of the transistors 3) and second contact pins 5b (e.g., drain contacts of the transistors 3). The contact pins 5a, 5b are firmly connected to contact areas in the base support plate 9. Conductor paths (not shown) run within or on surfaces of the base support plate 9 and forward the signals from each of the transistors 3.

Cooling elements 7 are arranged on sides of the transistors 3 that face away from the base support plate 9.

On a side facing the transistors 3, each of the cooling elements includes insulation layers 13 made of, for example, AlN. On another side of each of the cooling elements 7 (e.g., on the side of the transistors 3 that faces away from the base support plate 9), two shield plates are arranged (e.g., shield plate 11a on an upper side of the power module 1 and shield plate 11b on a lower side of the power module 1). The shield plates 11a, 11b provide external shielding from electromagnetic rays or waves from the power module 1. Such rays or waves are produced by the transistors 3 during operation. An area is thus defined between the two shield plates 11a, 11b. Electromagnetic radiation or waves are generated within the area but may not escape. Between the base support plate 9 and each of the two shield plates 11a, 11b, an RF cavity, within which the transistors 3 are arranged, is produced.

The cooling elements 7 include a hollow chamber, through which a cooling fluid (e.g., water) flows. As a result, the heat generated by the transistors 3 is conducted away from the side of the transistors 3 that faces away from the base support plate 9.

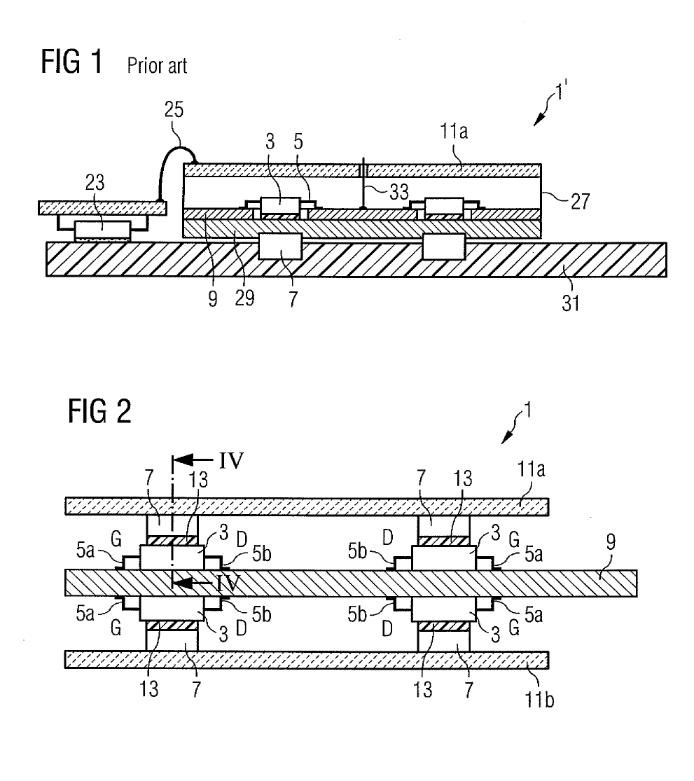

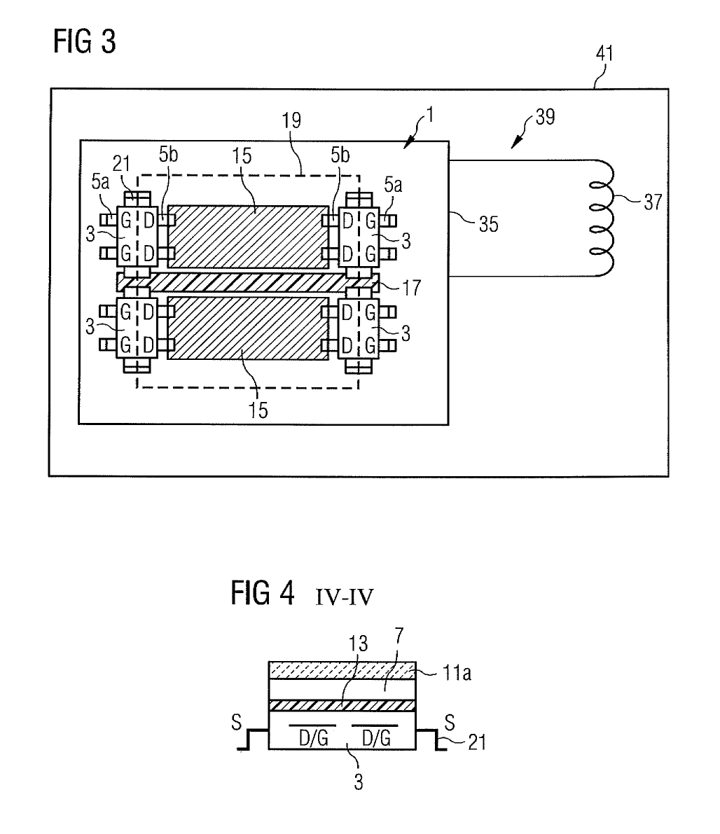

In contrast to the prior art shown in FIG. 1 (in FIG. 2, the power supply is not shown separately), the power electronic modules 3 are not in contact with the base support plate 9 across an entire surface. Instead, the power electronic modules 3 are in contact with the base support plate 9 only in localized areas via the contact pins 5a, 5b and/or via other contact pins 21, as can be seen in FIG. 3. This is made possible by the fact that the cooling elements 7 are arranged on the side of the transistors 3 that faces away from the base support plate 9. Thus, the transistors 3 may not be in contact with the base support plate 9 across an entire surface. Tolerances of the contact pins 5a, 5b and/or of the base support plate 9 may thus easily be compensated for.

FIG. 3 is a plan view of one embodiment of the power module 1, in which the shield plate 11a is not shown. FIG. 3 shows a total of 4 power electronic modules 3 arranged on a surface of the base support plate 9. Each of the transistors 3 has two contact pins 21 that serve as grounding connections. The pins 21 are also connected to the base support plate 9. Galvanic contacting of the grounding connections with a broader conductor path 17 in the base support plate 9 is achieved via a continuous line connection 19 that galvanically connects all the ground contact pins 21 with one another. A further conductor area 15 in the base support plate 9 connects each of two drain contact pins 5b of a transistor 3 to drain contact pins 5b of an adjacent transistor 3. In a similar way, each of gate contact pin may also be connected to gate contact pins of the nearest transistor 3.

The power module 1 is, for example, configured as a part of a high frequency amplifier unit 35 (schematically indicated) of a magnetic resonance tomography system 41. The high frequency amplifier unit 35 (schematically indicated) is a part of a high frequency antenna arrangement 39 (schematically indicated) for a body coil of the magnetic resonance tomography system 41. In addition to the high frequency amplifier unit 35, the high frequency antenna arrangement 39 also includes a high frequency antenna 37.

FIG. 4 is a cross-sectional view, perpendicular to the cross-section shown in FIG. 2, of the structure of an individual transistor 3, together with an insulation layer 13 located above the individual transistor. Although the insulation layer 13 is configured to be integral with the transistor 3, the insulation layer 13 may also be considered part of the cooling element 7 and any other parts added thereto.

The embodiments of the method and the devices described are purely exemplary and may be modified by those skilled in the art in a wide variety of ways without departing from the scope of the invention. Use of the indefinite article “a” or “an” does not exclude the possibility of more than one of the features in question being present.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A power module for a high frequency amplifier unit, the power module comprising:
a base support plate, on which at least one power electronic module is contacted via a number of contact pins; and
a shield plate that is arranged on a side of the power electronic module facing away from the base support plate, the at least one power electronic module being contactable with a cooling element on a side facing the shield plate.

2. The power module as claimed in claim 1, wherein the side of the at least one power electronic module facing away from the base support plate is the side facing the shield plate.

3. The power module as claimed in claim 1, wherein the high frequency amplifier unit is a high frequency amplifier unit of a body coil of a magnetic resonance tomography system.

4. The power module as claimed in claim 1, wherein the base support plate is configured without a cooling element and in an area above an area, in which the at least one power electronic module is positioned.

5. The power module as claimed in claim 1, wherein the base support plate has individual points, areas, or points and areas for galvanic contacting on a surface facing the at least one power electronic module.

6. The power module as claimed in claim 1, wherein the at least one power electronic module comprises at least two power electronic modules, the at least two power electronic modules being in contact with the base support plate at surfaces of the support plate that face away from each other.

7. The power module as claimed in claim 1, wherein the at least one power electronic module comprises at least two power electronic modules, each power electronic module of the at least two power electronic modules being in contact with a shared cooling element on the side facing away from the base support plate.

8. The power module as claimed in claim 1, wherein the at least one power electronic module has a grounding connection with the shield plate.

9. The power module as claimed in claim 1, wherein the at least one power electronic module has a grounding connection with the base support plate, and
wherein the shield plate is mechanically connected to the base support plate via the grounding connection.

10. The power module as claimed in claim 1, wherein the cooling element comprises a hollow chamber.

11. The power module as claimed in claim 10, wherein the hollow chamber contains a cooling fluid that flows through the hollow chamber.

12. The power module as claimed in claim 1, wherein the cooling element has an insulation layer that is in direct contact with the at least one power electronic module and electrically insulates, electromagnetically shields, or electrically insulates and electromagnetically shields the at least one power electronic module.

13. The power module as claimed in claim 1, wherein part of a surface of the at least one power electronic module is in contact with the base support plate.

14. A high frequency amplifier unit of a magnetic resonance tomography system, the high frequency amplifier unit comprising:
a plurality of power modules, each power module of the plurality of power modules comprising:
a base support plate, on which at least one power electronic module is contacted via a number of contact pins; and
a shield plate that is arranged on a side of the power electronic module facing away from the base support plate, the at least one power electronic module being contactable with a cooling element on a side facing the shield plate.

15. The high frequency amplifier unit as claimed in claim 14, wherein the high frequency amplifier unit is a high frequency amplifier unit of a body coil of the magnetic resonance tomography system.

16. The high frequency amplifier unit as claimed in claim 14, wherein the high frequency amplifier unit is a high frequency amplifier unit of a body coil of a magnetic resonance tomography system.

17. The high frequency amplifier unit as claimed in claim 14, wherein the base support plate is configured without a cooling element and in an area above an area, in which the at least one power electronic module is positioned.

18. A high frequency antenna arrangement comprising:
a high frequency antenna; and
a high frequency amplifier unit comprising:
a plurality of power modules, each power module of the plurality of power modules comprising:
a base support plate, on which at least one power electronic module is contacted via a number of contact pins; and
a shield plate that is arranged on a side of the power electronic module facing away from the base support plate, the at least one power electronic module being contactable with a cooling element on a side facing the shield plate.

19. A magnetic resonance tomography system comprising:
a high frequency antenna arrangement; and
a high frequency amplifier unit comprising:
a plurality of power modules, each power module of the plurality of power modules comprising:
a base support plate, on which at least one power electronic module is contacted via a number of contact pins; and
a shield plate that is arranged on a side of the power electronic module facing away from the base support plate, the at least one power electronic module being contactable with a cooling element on a side facing the shield plate.

20. A method of manufacturing a power module for a high frequency amplifier unit, the method comprising:
providing a base support plate;
bringing at least one power electronic module into contact with the base support plate via a number of contact pins;
arranging a shield plate on a side of the at least one power electronic module facing away from the base support plate; and
bringing the at least one power electronic module into contact with a cooling element at a side facing the shield plate.
